(19) United States
(12) Patent Application Publication
(10) Pub. No.: US 2015/0079309 A1
(43) Pub. Date: Mar. 19, 2015

(54) COATING OF CONTAINERS USING PLASMA NOZZLES

(71) Applicant: KRONES AG, Neutraubling (DE)

(72) Inventors: Jochen Krueger, Hagelstadt (DE); Heinz Humele, Thalmassing (DE)

(21) Appl. No.: 14/385,969

(22) PCT Filed: Jan. 16, 2013
(86) PCT No.: PCT/EP2013/050707

§ 371 Date: Sep. 17, 2014

(30) Foreign Application Priority Data
Apr. 13, 2012 (DE) 102012206081.2

(51) Int. Cl. C23C 16/50; C23C 16/455

(52) U.S. Cl. CPC C23C 16/50; C23C 16/455
USPC 427/569; 118/723 R

(57) ABSTRACT

A device used for plasma-enhanced coating of a container, e.g. a plastic bottle, and/or a container blank, e.g. a container preform, with at least one high-frequency source, at least one gas feed for feeding process gas, and at least one plasma source, e.g. a plasma nozzle. The plasma source has an inner electrode surrounded by a nozzle tube, the plasma source is adapted to be introduced in a container to be coated and configured such that it is able to generate a plasma under ambient pressure, e.g. in a pressure range of 800 to 1,200 hPA, and the plasma can be discharged from a nozzle tube end. The temperature of the generated plasma lies within the range of the ambient temperature, e.g. between 10 and 50 ° C. The nozzle tube of the plasma source includes a longitudinal nozzle tube element and a lateral nozzle tube element projecting laterally from the longitudinal nozzle tube element (201). Plasma is dischargeable through the lateral nozzle tube end.

### CROSS-REFERENCE TO RELATED APPLICATION

The present application is the US national phase of International Patent Application No. PCT/EP2013/050707, filed Jan. 16, 2013, which application claims priority of German Application No. 102012206081.2, filed Apr. 13, 2012. The priority application, DE 102012206081.2, is hereby incorporated by reference.

### BACKGROUND

For reducing the permeability of the walls of containers/hollow bodies, e.g. with respect to undesirable substances, it is advantageous to provided these walls with a barrier layer, e.g. through plasma-enhanced chemical vapor deposition (PECVD), as described e.g. in EP0881197A2.

Such barrier layers are e.g. required for reducing the transmission rates of gases through the plastic wall of a container. CO₂ losses from the product filled into the container or an ingress of oxygen into the product can be minimized in this way. In addition, it is thus possible to protect the product against substances which originate from the container material and which may cause changes in the color or the taste of the product.

For coating containers by means of a plasma treatment, e.g. for plasma coating the inner surfaces of plastic bottles by means of plasma, a so-called high-frequency plasma may, for example, be used in so-called low-pressure plants.

To this end, the interior of the container is first evacuated to a pressure in the range of 1-10 Pa. The area of the surface to be coated, e.g. the interior of the container, has then introduced therein a process gas, which is used for forming the layer, the so-called “precursor”, whereby the pressure in the interior of the container may increase to 10-30 Pa.

With the aid of electromagnetic radiation, e.g. microwave or high-frequency or other electric fields, this gas or mixture of gases can then be transferred, partly or fully, into a plasma state and, in so doing, be broken down into its components. Parts of the gas undergo a plasma-enhanced reaction in the gaseous phase or on the surface of the substrate to be coated, e.g. on the inner wall of a plastic bottle, and condense on this surface thus forming a closed layer.

One of the drawbacks of this coating technique is e.g. the complex vacuum technology required for this purpose and also the sometimes substantial thermal loads acting on the substrate. This is critical in particular as regards plastic surfaces, since these surfaces may be damaged by this kind of treatment.

In the meantime plasma sources have become known, which are able to generate plasma under ambient pressure, so-called plasma nozzles, described e.g. in EP1335641, US 2007116891, EP0761415 and US20020179575.

### OBJECT

It is therefore the object of the present disclosure to improve a device for coating containers and/or container shapes by means of a plasma treatment, e.g. the coating of plastic bottles and/or container blanks, in particular with regard to minimizing the complexity and increasing the efficiency of the coating device.

### SUMMARY OF THE DISCLOSURE

A device according to the present disclosure used for plasma-enhanced coating of a container, e.g. a plastic bottle, and/or a container blank, e.g. a container preform, may comprise at least one high-frequency source, at least one gas feed for feeding process gas, and at least one plasma source, e.g. a plasma nozzle. The plasma source may comprise an inner electrode and said inner electrode may be surrounded by a nozzle tube. The at least one plasma source can thus be introduced in a container to be coated and it can be configured such that it is able to convert the process gas, partly or fully, into a plasma under ambient pressure, e.g. in a pressure range of 800 to 1,200 hPA, and the plasma can be discharged from a nozzle tube end, the temperature of the generated plasma lying within the range of the ambient temperature, e.g. between 10 and 50° C. The nozzle tube of the plasma source may comprises a longitudinal nozzle tube element and a lateral nozzle tube element, and said lateral nozzle tube element may project laterally from the longitudinal nozzle tube element, and plasma may be dischargeable through the lateral nozzle tube end.

This has the advantage that an otherwise commonly practised expensive and complicated vacuum generation in the plasma treatment area, e.g. within and/or without a container to be coated, can be avoided, and that thermal loads on the substrate to be coated, e.g. a plastic bottle, can be minimized so as to avoid damage to the substrate.

The process gas that may here be used for depositing quartzous layers may e.g. be a mixture of oxygen and a gaseous organosilicon monomer, such as hexamethyldisiloxane (HMDSO), HMDSN, TEOS, TMOS, HMCTSO, APTMS, SiH4, TMS, OMCTS or similar compounds.

Analogously, C₂H₂, C₂H₄, CH₄, C₆H₆ or other carbonic swelling substances may be used in the process gas for depositing carbonic layers (so-called diamond like carbon “DLC” layers).

In addition, the plasma source may be movable linearly, e.g. parallel and/or transversely to the direction of gravity, and/or rotatively about the longitudinal axis and/or a parallel axis of the longitudinal nozzle tube element.

Likewise, the container to be coated may be movable relative to the plasma source linearly, e.g. parallel and/or transversely to the direction of gravity, and/or rotatively about the longitudinal axis of the container and/or rotatively about an axis that is parallel to the longitudinal axis of the container.

It is also imaginable that the container is rotatable about and/or translatively movable along some other axis, which is not parallel to the direction of gravity or to the longitudinal axis or the parallel axis of the longitudinal nozzle tube element.

This allows e.g. that the discharge of plasma can advantageously follow the container contour at a constant distance from the container wall to be coated.

The above described degrees of movement of the plasma source and/or of a container to be coated offer, among other advantages, the advantage that e.g. a plasma source having a lateral nozzle tube element/having lateral nozzle tube elements can more easily be introduced in a container and that the discharge of the plasma from a nozzle tube end can take place close to the substrate, e.g. preferably with a distance of 0.1-2 cm between the nozzle tube end and the substrate.

Furthermore, it is imaginable that the nozzle tube ends are movable, e.g. provided with controllable elements such as controllable pivotable flaps, for controlling the propagation direction and the discharge angle of the plasma discharged, and for limiting e.g. the plasma discharge angle to a range of 30° to 170°.

The term plasma discharge angle should here and in general be understood as the angle between the propagation direction of the plasma and the longitudinal axis of the longitudinal nozzle tube element.

The plasma source may comprise a plurality of nozzle tubes and electrodes.

The plasma source may, for example, comprise at least one longitudinal nozzle tube with an electrode, and the nozzle tube end of the longitudinal nozzle tube element may open at the end of the plasma source in the direction of gravity, and may further comprise a plurality of lateral nozzle tube elements with electrodes that may laterally project from the longitudinal nozzle tube element at regular or irregular intervals. The plasma may here be discharged through the lateral nozzle tube ends and through the longitudinal nozzle tube end.

The longitudinal nozzle tube may, however, also be closed at its longitudinal end, so that plasma can only be discharged through the lateral nozzle tube ends.

The electrodes suitable for insertion in the plasma source may e.g. be pin electrodes. The ends of the electrodes may e.g. taper or they may be rounded off.

Furthermore, a device according to the present invention used for plasma-enhanced coating of substrates may be configured as a rotary machine comprising a plurality of treatment units for plasma-enhanced coating of containers and/or container blanks.

In a method used for plasma-enhanced coating of substrates, such as a container, e.g. a plastic bottle, and/or of a container blank, e.g. a container preform, a plasma source may have supplied thereto a process gas and the process gas may be converted, partly or fully, into a plasma. The plasma can here be ignited at the end of at least one inner electrode, which may have applied thereto a high frequency, under ambient pressure, e.g. in a pressure range of 800 to 1,200 hPA, and at temperatures in a range of e.g. 10 to 50° C., and it can be discharged through a nozzle tube end of the nozzle tube element surrounding the inner electrode and coat a substrate, e.g. a container, such as a plastic bottle, and/or a container blank, e.g. a container preform.

It is also possible to deposit layers, e.g. multi-layered systems comprising layers of different compositions and layer characteristics, in a plurality of coating steps. For example, an intermediate layer may be deposited as an adhesive agent, e.g. silicon oxide with methyl group residues, between the substrate, e.g. a plastic bottle, and the actual coating, e.g. a gas barrier layer.

For example, an adhesive agent layer consisting of amorphous carbon may be applied first, this layer being then followed by a barrier layer of silicon oxide. DLC layers may be applied, depending on the layer thickness, as barrier layers, e.g. for layer thicknesses in the range of 50 to 200 nm, or as adhesive agents, e.g. for layer thicknesses in the range of 1 to 10 nm.

A barrier layer may additionally be provided/coated with a protective layer so as to protect it e.g. against chemical attacks through the product. Alkaline products or products which are only slightly acidic may e.g. partially dissolve and damage a SiOx layer.

Also additional functional layers may be applied for UV protection, abrasion protection, easier emptying of residues through surface modification, reduction of gushing (abrupt foaming after pressure relief during the bottling process or when the bottles are opened by the consumer), surface modifications allowing easier application of labels by means of an adhesive or easier direct printing.

Likewise, coatings having a sterilizing effect, e.g. coatings with silver ions or with reactive layers, e.g. singlet-oxygen-containing or singlet-oxygen-creating layers, are imaginable.

It is also imaginable to additionally apply merely decorative layers so as to accomplish color, frosted, gloss and reflection effects.

In addition, e.g. also “sandwich” coatings can be provided in an advantageous manner. In such coatings, e.g. a barrier layer is provided between two adhesive agent layers, or between an adhesive agent layer and some other functional or decorative layer.

In this way, multi-layer coatings can advantageously be produced, said coatings having characteristics which are otherwise difficult to combine. Good barrier layers are e.g. often brittle/friable and have poor adhesion properties, whereas layers having good adhesion properties often have hardly any barrier effect (e.g. “soft” silicon oxide layers) or they have an undesirably intensive brown hue (DLC layers).

It is also possible to accomplish in one or in a plurality of coating steps a smooth/continuous transition in the layer material and/or the layer composition and/or the layer characteristics within one layer or between different layers. A silicon oxide layer that becomes harder as the thickness increases may e.g. be produced.

### BRIEF DESCRIPTION OF THE SEVERAL VIEWS OF THE DRAWINGS

The figures enclosed show exemplarily:

FIG. 1: plasma source.

FIG. 2: alternative plasma source in a container.

FIG. 3: alternative plasma source in a container.

FIG. 4: alternative plasma source in a container.

FIG. 5: alternative plasma source in a container.

### DETAILED DESCRIPTION OF THE PREFERRED EMBODIMENTS

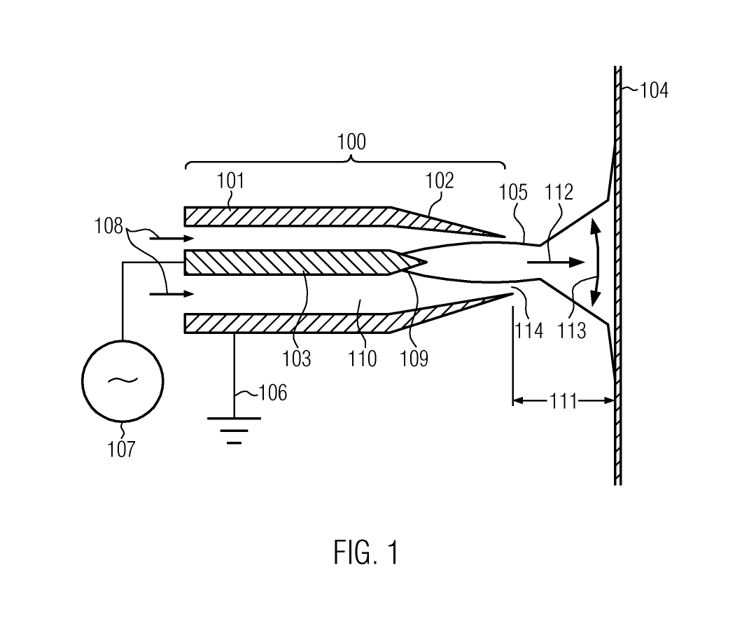

FIG. 1 shows exemplarily the diagram of a plasma source 100 as a plasma nozzle. The plasma source may here comprise a nozzle tube 101 with a nozzle tube end 102.

The nozzle tube 101 may comprise an inner electrode 103, e.g. a pin electrode, which is adapted to have applied thereto a high frequency from the high-frequency source 107. The nozzle tube 101 may here be connected to ground or earth potential 106. A process gas 108 may be supplied to the cavity 110 between the inner electrode and the nozzle tube 101. At the end 109 of the inner electrode, the process gas can be converted, partly or fully, into a plasma 105 through electric discharges, and the plasma 105 can be discharged from the nozzle tube end 102 and impinge on the substrate 104 to be coated, e.g. a container wall or a container blank surface, which may be spaced apart from the nozzle tube end 102 at a distance 111, preferably a distance of 0.1-2 cm. The nozzle tube end 102 may be shaped such that it tapers conically to the plasma discharge opening 112.

In addition, it is imaginable that the nozzle tube end 102 may be provided with controllable pivotable flaps (not shown), which are capable of controlling the plasma propagation direction 112 and the plasma discharge angle 113 insofar as e.g. the discharge angle 113 of the plasma can be limited to a range of 30° to 170°.

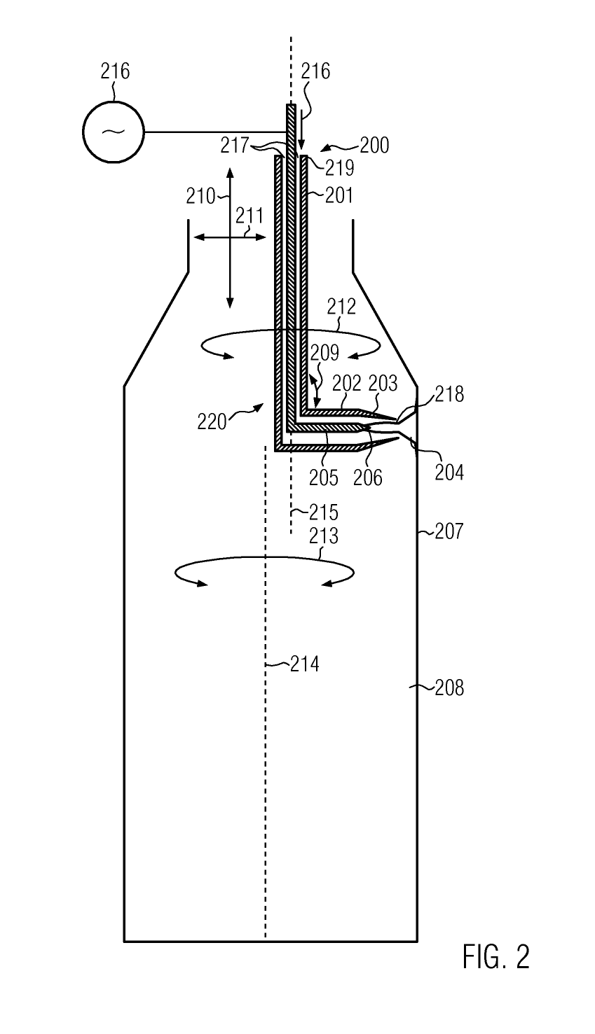

FIG. 2 shows exemplarily a plasma source 200 that is adapted to be inserted into a container 208. The plasma source 200 may here consist of a longitudinal nozzle tube element 201 and of a lateral nozzle tube element 202 with a nozzle tube end 203, said nozzle tube element 202 projecting laterally from said nozzle tube element 201. The angle 209 between the lateral nozzle tube element 202 and the longitudinal nozzle tube element 201 may lie between 45° and 135°. The preferred angle 209 is an angle between 80° and 100° or, as shown in FIG. 2, an angle of 90°.

It is here also imaginable that the lateral nozzle tube element 202 is pivotable, e.g. by means of a ball and socket joint connection between the lateral nozzle tube element 202 and the longitudinal nozzle tube element 201. This is another possibility of controlling the propagation direction and the discharge angle of the plasma, and of limiting e.g. the plasma discharge angle to a range of 30° to 170°.

The inner electrode 205, which may be encompassed by the nozzle tube elements 201 and 202 and which may have applied thereto a high frequency from the high-frequency source 216, can here follow the geometrical profile of the contour of the nozzle tube elements 201 and 202.

The plasma source can here be movable linearly, e.g. parallel 210 and/or transversely 211 to the direction of gravity, and/or rotatively about the longitudinal axis 215 and/or a parallel axis 214 of the longitudinal nozzle tube element. Likewise, the container 208 may be movable relative to the plasma source 200 linearly, e.g. parallel and/or transversely to the direction of gravity, and/or rotatively about the longitudinal axis of the container and/or rotatively about an axis 214 that is parallel to the longitudinal axis of the container.

It is also imaginable that the container 208 is rotatable about and/or translatively movable along some other axis, which is not parallel to the direction of gravity or to the longitudinal axis 215 or the parallel axis 214 of the longitudinal nozzle tube element.

This allows e.g. that the discharge of plasma can advantageously follow the container contour at a constant distance from the container wall to be coated.

The process gas 216 can be supplied to the cavity between the inner electrode 205 and the nozzle tube elements 201 and 202 and, at the end 206 of the electrode 205, it can be converted partly or fully into a plasma 204 that can be discharged through the plasma discharge opening 218 at the nozzle tube end 203 and can thus coat e.g. an inner wall 207 of the container 208.

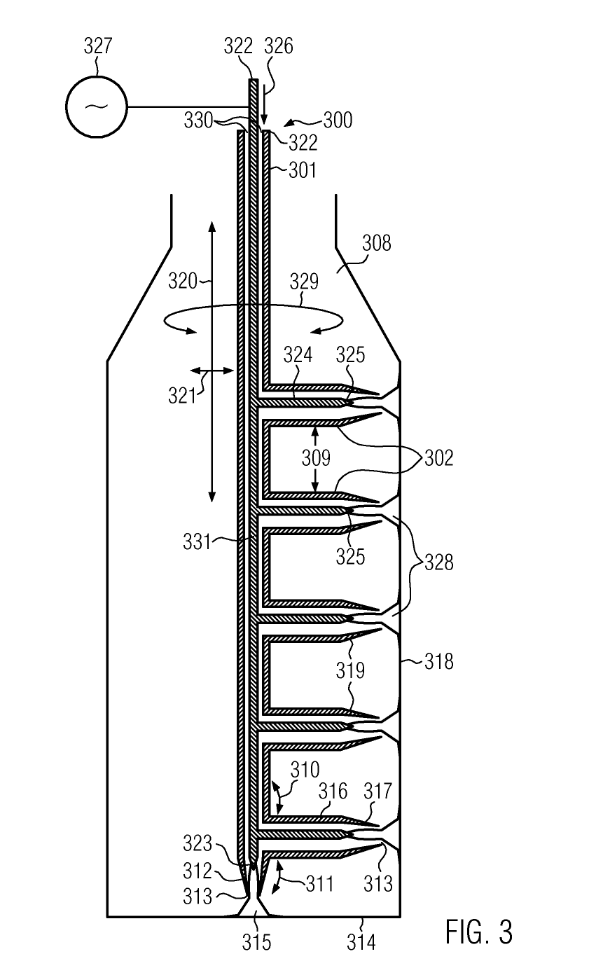

FIG. 3 shows exemplarily a further plasma source 300 that can be introduced in a container 308. The plasma source 300 may here be provided with a longitudinal nozzle tube element 301 from which a plurality of lateral nozzle tube elements 302 may laterally project. The lateral nozzle tube elements 302 may be provided on one side or also on a plurality of sides along the longitudinal axis of the longitudinal nozzle tube. The vertical distances 309 between neighboring lateral nozzle tube elements 302 may here be regular or irregular, and may e.g. be distances between 1 and 4 cm, preferably approx. 2 cm.

The end 312 located in the direction of gravity of the longitudinal nozzle tube element 301 may also be configured as a nozzle tube end provided with a plasma discharge opening 313 so that the bottom 314 of the container 308 can be coated with the discharged plasma 315 in an advantageous manner. Said longitudinal nozzle tube end 312 may define e.g. an angle 311 between 45° and 135° with the directly adjacent lateral nozzle tube element 316.

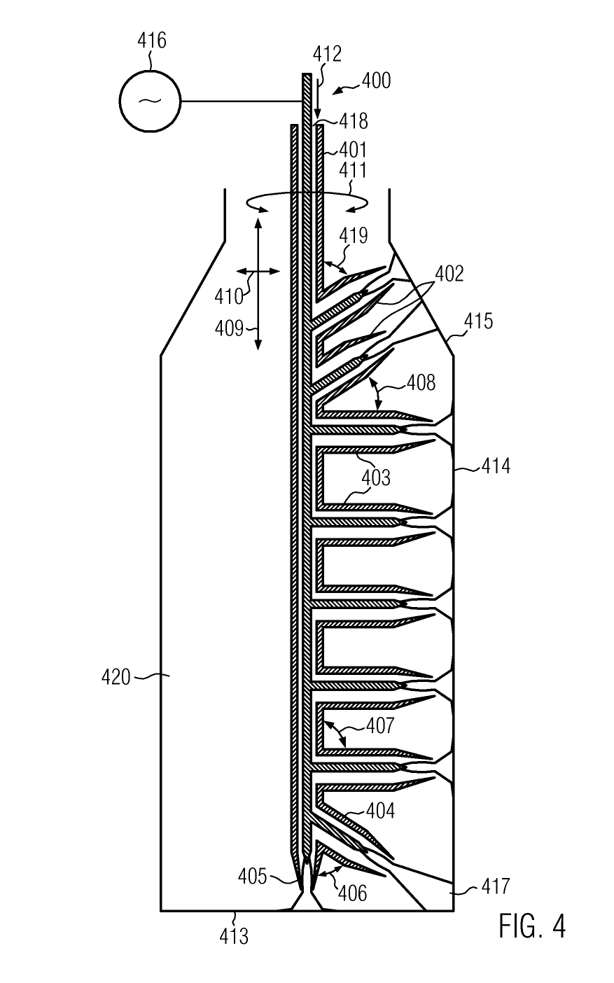

As can be seen in the figure, the angles 310 between the lateral nozzle tube elements 302, 316 and the longitudinal nozzle tube element 301 may e.g. be 90° angles, but they may also be in the range of 45° to 135° or in the range of 80° to 100° (cf. in this respect also FIG. 4).

Just as in the case of the above described plasma source 200, the plasma source 300 may be movable linearly, e.g. parallel 320 and/or transversely 321 to the direction of gravity, and/or rotatively 329 about the longitudinal axis and/or a parallel axis or at an angle relative to the axis of the longitudinal nozzle tube element 301 Likewise, the container 308 may be movable relative to the plasma source 300 linearly, e.g. parallel and/or transversely to the direction of gravity, and/or rotatively about the longitudinal axis of the container and/or rotatively about an axis parallel to the longitudinal axis of the container.

It is also imaginable that the container 308 is rotatable about and/or translatively movable along some other axis, which is not parallel to the direction of gravity or to the longitudinal axis or the parallel axis of the longitudinal nozzle tube element 301.

The inner electrode element 322 may comprise a plurality of inner electrodes whose number may correspond to that of the nozzle tube elements, e.g. a longitudinal electrode 331 encompassed by the longitudinal nozzle tube element 301, and lateral electrodes 324 encompassed by the lateral nozzle tube elements 302, 316.

The process gas 326 may be supplied to the cavity 330 between the inner electrode element 322 and the nozzle tube elements 301, 302 and 316. At the ends 323, 325 of the inner electrodes, the process gas can be converted, partly or fully, into a plasma 328, which can be discharged through the plasma discharge openings 313 of the nozzle tube ends 312, 317 and 319 and can thus coat e.g. an inner wall 318 and/or the bottom 314 of the container 308.

FIG. 4 shows exemplarily a further plasma source 400 which is configured analogously to the above described plasma source 300, but which exhibits an exemplary arrangement of the lateral nozzle tube elements 402, 403 and 404 whose orientation relative to the longitudinal nozzle tube element 401, characterized by the angles 406, 407, 408 between the longitudinal nozzle tube element 401 and the lateral nozzle tube elements 404, 403, 402, may be different from 90°.

For example, the angle 406 between the longitudinal nozzle tube end 405 and the neighboring nozzle tube end 404 may be smaller than 90°, e.g. between 10° and 85°, and the angle 408 between the lateral nozzle tube 402 and the longitudinal nozzle tube element 401 may be larger than 90° and lie e.g. in the range of 95° to 170°.

According to an advantageous embodiment, one or a plurality of lateral nozzle tube elements 402, 403, 404, which are arranged closer to the process gas inlet 418 leading into the longitudinal nozzle tube element, may be tilted towards said process gas inlet 418 (in FIG. 4 e.g. upwards), i.e. the angle 419 between the lateral nozzle tube element 402 and the process gas inlet 418 of the longitudinal nozzle tube element 401 may be less than 90° and may preferably lie between 10° and 85°. One or a plurality of lateral nozzle tube elements that are more remote from the process gas inlet 418 may be tilted away from the process gas inlet 418 (in FIG. 4 e.g. downwards).

One of the advantages of this arrangement is that e.g. corners, such as the corner 417 between the container bottom 413 and the container wall 414, or oblique container walls, e.g. the container wall slope 415, can be coated more easily.

Apart from the above described angles, the plasma source 400 may have the same features as the plasma source 300. The plasma source 400 may, for example, be movable linearly, e.g. parallel 409 and/or transversely 410 to the direction of gravity, and/or rotatively 411 about the longitudinal axis and/or a parallel axis of the longitudinal nozzle tube element Likewise, the container 420 may be movable relative to the plasma source 400 linearly, e.g. parallel and/or transversely to the direction of gravity, and/or rotatively about the longitudinal axis of the container and/or rotatively about an axis parallel to the longitudinal axis of the container.

It is also imaginable that the container 420 is rotatable about and/or translatively movable along some other axis, which is not parallel to the direction of gravity or to the longitudinal axis or the parallel axis of the longitudinal nozzle tube element 401.

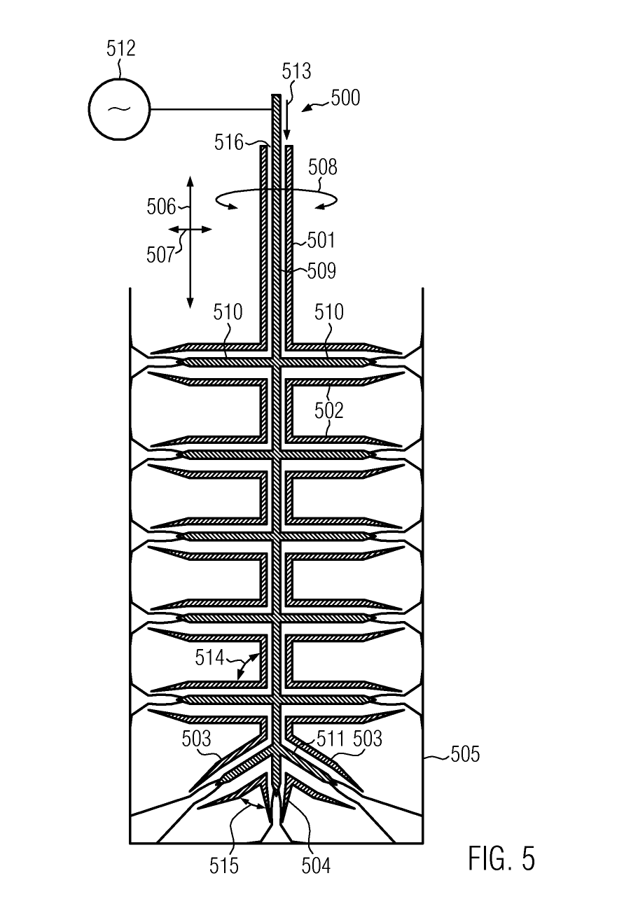

FIG. 5 shows exemplarily a further plasma source 500, which may comprise a longitudinal nozzle tube element 501 from which lateral nozzle tube elements 502, 503 project in pairs from opposed sides of the longitudinal nozzle tube element 501.

The angles 515, 514 between the lateral nozzle tube elements 502, 503 and the longitudinal nozzle tube element 501 may lie in the range between 45° and 135°. Preferably, these angles are, however, pairwise identical. The angle 515 between the longitudinal nozzle tube end 504 and the nearest lateral nozzle tube elements 503 may preferably be smaller than 90° and may, for example, lie between 10° and 85°.

Just as in the case of the above described plasma sources 200, 300 and 400, the plasma source 500 may be movable linearly, e.g. parallel 506 and/or transversely 507 to the direction of gravity, and/or rotatively 508 about the longitudinal axis and/or a parallel axis of the longitudinal nozzle tube element Likewise, the container 500 may be movable relative to the plasma source 500 linearly, e.g. parallel and/or transversely to the direction of gravity, and/or rotatively about the longitudinal axis of the container and/or rotatively about an axis parallel to the longitudinal axis of the container.

It is also imaginable that the container 500 is rotatable about and/or translatively movable along some other axis, which is not parallel to the direction of gravity or to the longitudinal axis or the parallel axis of the longitudinal nozzle tube element 501.

Neighboring nozzle tube elements may also be vertically displaced relative to one another and they may e.g. be able to rotate e.g. about the longitudinal nozzle tube element.

By means of the increased number of lateral nozzle tube elements in comparison with an embodiment having its lateral nozzle tube elements not arranged in pairs, the surface area that can be coated per unit time can be increased and the amount of time required for coating can thus be reduced. It would be imaginable to optimize the coating time still further by another increase in the number of lateral nozzle tube elements, e.g. by means of a collar of lateral nozzle tube elements comprising more than two lateral nozzle tube elements per collar.

In addition, it is imaginable that a plasma source comprises lateral nozzle tube elements which are adapted to be extended from a longitudinal nozzle tube telescopically and/or in an umbrella-like manner and/or which are adapted to be folded out from said longitudinal nozzle tube.

What is claimed is:

1. A device used for plasma-enhanced coating of at least one of a container or a container blank, comprising at least one high-frequency source, at least one gas feed for feeding process gas, and at least one plasma source, the plasma source including an inner electrode, said inner electrode surrounded by a nozzle tube, the at least one plasma source is adapted to be introduced in a container to be coated and configured such that it is able to generate a plasma under ambient pressure, and wherein the plasma can be discharged from a nozzle tube end, and the temperature of the generated plasma lying within a range of ambient temperature, the nozzle tube of the plasma source comprising a longitudinal nozzle tube element and a lateral nozzle tube element, said lateral nozzle tube element projecting laterally from the longitudinal nozzle tube element, and plasma being dischargeable through the lateral nozzle tube end.

2. The device according to claim 1, the nozzle tube end including controllable element, by means of which the propagation direction and the discharge angle of the plasma discharged can be controlled, and a discharge angle of the plasma discharged can be limited to within a range of 30° to 170°.

3. The device according to claim 1, the plasma source being movable at least one of linearly, rotatively about the longitudinal axis, rotatively about an axis a parallel to an axis of the longitudinal nozzle tube element.

4. The device according to claim 1, the container to be coated being movable relative to the plasma source at least one of linearly, rotatively about the longitudinal axis of the container, rotatively about an axis that is parallel to the longitudinal axis of the container, or one of rotatively about or translatively movable along an axis, which is not parallel to the direction of gravity or to the longitudinal axis or the parallel axis of the longitudinal nozzle tube element.

5. The device according to claim 1, the plasma source comprising a plurality of nozzle tubes and electrodes.

6. The device according to one claim 1, the plasma source comprising at least one longitudinal nozzle tube with an electrode, the nozzle tube end of the longitudinal nozzle tube element opening at the end of the plasma source in the direction of gravity, and further comprising a plurality of lateral nozzle tube elements with electrodes which laterally project from the longitudinal nozzle tube element at regular or irregular intervals, and plasma being dischargeable through the lateral nozzle tube ends and through the longitudinal nozzle tube end.

7. The device according to claim 6, the longitudinal nozzle tube being closed at its longitudinal end.

8. The device according to claim 1 the end of the electrode(s) one of tapering or being rounded off.

9. The device according to claim 1, wherein the device is configured as a rotary machine comprising a plurality of treatment units for plasma-enhanced coating of at least one of containers or container blanks.

10. A method of plasma-enhanced coating of at least one of a container, or a container blank, comprising:
generating a plasma in a plasma source, under ambient pressure, and at temperatures in a range of 10 to 50° C., and
coating at least one of a substrate, or a container blank, by means of the plasma discharged from the plasma source.

11. The method according to claim 10, further comprising coating the substrate in a plurality of coating steps with layers having different compositions and layer characteristics, an intermediate layer being applied in a first coating step as an adhesive agent, between the substrate and a subsequent second coating.

12. A method according to claim 10, further comprising coating the substrate in one or more coating steps with a smooth transition in at least one of the layer material, the layer composition, the layer characteristics within one layer, or between different layers.

13. The device according to claim 1, the ambient pressure being in a range of 800 to 1,200 hPA.

14. The device according to claim 1, the ambient temperature being between 10 and 50° C.

15. The device according to claim 4, and in the container to be coated being movable relative to the plasma source, the container is movable in a direction that is one of parallel or transverse to the direction of gravity.

16. The device according to claim 1, the container being a plastic bottle.

17. The device according to claim 1, the container blank being a container preform.

18. The method according to claim 10, and in coating by means of the plasma discharged from the plasma source, the container being a plastic bottle.

19. The method according to claim 10, and in coating by means of the plasma discharged from the plasma source, the container blank being a container preform.

20. The method according to claim 10, and in generating a plasma in a plasma source, under ambient pressure, the pressure is in a range of 800 to 1,200 hPA
